(19) United States
(12) Patent Application Publication
(10) Pub. No.: US 2007/0232062 A1
(43) Pub. Date: Oct. 4, 2007

(54) Damascene interconnection having porous low k layer followed by a nonporous low k layer

(76) Inventor: Takeshi Nogami, Hopewell Junction, NY (US)

Correspondence Address: MAYER & WILLIAMS PC, 251 NORTH AVE. WEST, 2ND FLOOR, WESTFIELD, NJ, 07090, US

(21) Appl. No.: 11/395,963

(22) Filed: Mar. 31, 2006

(51) Int. Cl. H01L 21/4763

(52) U.S. Cl. 438/638; 257/E21.577

(57) ABSTRACT

A method is provided for fabricating a damascene interconnection. The method begins by forming on a substrate a porous low k dielectric layer and forming a resist pattern over the low k dielectric layer to define a first interconnect opening. The porous low k dielectric layer is etched through the resist pattern to form the first interconnect opening. The resist pattern is removed and a barrier layer is applied to line the first interconnect opening. An interconnection is formed by filling the first interconnect opening with a conductive material. The interconnection is planarized to remove excess material and a portion of the porous low k dielectric layer damaged by the planarizing step is removed. A nonporous low k dielectric layer is applied after the damaged portion of the porous low k dielectric layer is removed. The interconnection is planarized by removing an excess portion of the nonporous low k dielectric layer.

### FIELD OF THE INVENTION

The present invention relates generally to single and dual damascene interconnections for integrated circuits, and more specifically to a single or dual damascene interconnection having a porous low k layer.

### BACKGROUND OF THE INVENTION

The manufacture of integrated circuits in a semiconductor device involves the formation of a sequence of layers that contain metal wiring. Metal interconnects and vias which form horizontal and vertical connections in the device are separated by insulating layers or inter-level dielectric layers (ILDs) to prevent crosstalk between the metal wiring that can degrade device performance. A popular method of forming an interconnect structure is a dual damascene process in which vias and trenches are filled with metal in the same step to create multi-level, high density metal interconnections needed for advanced high performance integrated circuits. The most frequently used approach is a via first process in which a via is formed in a dielectric layer and then a trench is formed above the via. Recent achievements in dual damascene processing include lowering the resistivity of the metal interconnect by switching from aluminum to copper, decreasing the size of the vias and trenches with improved lithographic materials and processes to improve speed and performance, and reducing the dielectric constant (k) of insulators or ILDs by using so-called low k materials to avoid capacitance coupling between the metal interconnects. The expression “low-k” material has evolved to characterize materials with a dielectric constant less than about 3.9. One class of low-k material that have been explored are organic low-k materials, typically having a dielectric constant of about 2.0 to about 3.8, which may offer promise for use as an ILD.

Recently, porous low k materials have been employed in damascene processes. A void-filled, or porous dielectric material has a lower dielectric constant than the fully dense void-free or nonporous version of the same material. Such porous low-dielectric constant materials may be deposited by chemical vapor deposition (CVD), or may be spun on in liquid solution and subsequently cured by heating to remove the solvent. Porous low-dielectric constant materials are advantageous in that they have a dielectric constant of 3.0 or less. Examples of such porous low-dielectric constant materials include porous SiLK™ and porous silicon carbonated oxide, as examples. A porogen may be included in the porous low-dielectric constant materials to cause the formation of the pores.

Many of the porous low k materials, however, have properties that are incompatible with other materials employed to fabricate semiconductor devices or are incompatible with processes employed to fabricate the semiconductor devices. The very nature of the desirable porous structure of these materials also make them fragile and easily damaged by Chemical Mechanical Polishing (CMP) processes. For example, layers formed from low dielectric materials are often structurally compromised by CMP processes through erosion, as well as adsorption of CMP slurry chemicals. Etching processes such as reactive ion etching often produce micro-trenches and rough surfaces in layers formed from materials having low dielectric constants, which often reduces the reliability of the interconnects by causing leakage between neighboring wires, these materials are problematic to integrate into damascene fabrication processes.

To overcome this problem, attempts have been made to form a layer of a nonporous low k material over a thicker layer of porous low k material prior to etching the trench or via, thereby obtaining most of the advantages of the porous material. In this way the porous low k material is effectively protected by the nonporous low k material during the subsequent CMP processing. However, one problem with this approach arises because the etch rate of the porous low k material during the formation of the trench or via is greater than the etch rate through the nonporous layer. As a result, when the trench or via is formed, a recess is often formed in the porous low k layer because of excess etching that arises from the different etch rates. The recess can reduce the reliability of the interconnect.

Accordingly, it would be desirable to provide a damascene interconnect structure that includes a porous low k material to reduce the structure's overall dielectric constant but which is also less fragile to mechanical damage from CMP and other processes.

### SUMMARY OF THE INVENTION

In accordance with the present invention, a method is provided for fabricating a damascene interconnection. The method begins by forming on a substrate a porous low k dielectric layer and forming a resist pattern over the low k dielectric layer to define a first interconnect opening. The porous low k dielectric layer is etched through the resist pattern to form the first interconnect opening. The resist pattern is removed and a barrier layer is applied to line the first interconnect opening. An interconnection is formed by filling the first interconnect opening with a conductive material. The interconnection is planarized to remove excess material and a portion of the porous low k dielectric layer damaged by the planarizing step is removed. A nonporous low k dielectric layer is applied after the damaged portion of the porous low k dielectric layer is removed. The interconnection is planarized by removing an excess portion of the nonporous low k dielectric layer.

In accordance with one aspect of the invention, a capping layer is formed on the porous dielectric layer and both the capping layer and the porous low k layer are etched through the resist pattern.

In accordance with another aspect of the invention, the damaged portion of the dielectric layer is removed by a wet etching process.

In accordance with another aspect of the invention, the wet etching process employs HF as an etchant.

In accordance with another aspect of the invention, the porous low k dielectric has a dielectric constant less than about 2.5 and the nonporous low k dielectric has a dielectric constant of between about 2.6 and 3.3.

In accordance with another aspect of the invention, the porous low k dielectric layer is etched by Reactive Ion Etching (RIE).

In accordance with another aspect of the invention, the porous low k layer includes SiLK™.

In accordance with another aspect of the invention, the porous low k layer includes DendriGlass™.

In accordance with another aspect of the invention, the nonporous low k layer includes SiOCH.

In accordance with another aspect of the invention, the nonporous low k layer is selected from the group consisting of Black Diamond™ or Coral™.

In accordance with another aspect of the invention, the first interconnect opening comprises a via.

In accordance with another aspect of the invention, the first interconnect opening comprises a via and a trench connected thereto.

In accordance with another aspect of the invention the planarizing is performed by CMP.

In accordance with another aspect of the invention, the damascene interconnection is a dual damascene interconnection.

In accordance with another aspect of the invention, the conductive material is copper.

In accordance with another aspect of the invention, an integrated circuit is provided that has a damascene interconnection constructed in accordance with any of the aforementioned methods.

### BRIEF DESCRIPTION OF THE DRAWINGS

FIGS. 1-13 show cross-sectional views illustrating the formation of a dual damascene structure constructed in accordance with one embodiment of the present invention.

### DETAILED DESCRIPTION

The methods and structures described herein do not form a complete process for manufacturing semiconductor device structures. The remainder of the process is known to those of ordinary skill in the art and, therefore, only the process steps and structures necessary to understand the present invention are described herein.

The present invention can be applied to microelectronic devices, such as highly integrated circuit semiconductor devices, processors, micro electromechanical (MEM) devices, optoelectronic devices, and display devices. In particular, the present invention is highly useful for devices requiring high-speed characteristics, such as central processing units (CPUs), digital signal processors (DSPs), combinations of a CPU and a DSP, application specific integrated circuits (ASICs), logic devices, and SRAMs.

Herein, an opening exposing a lower interconnection is referred to as a via, and a region where interconnections will be formed is referred to as a trench. Hereinafter, the present invention will be described by way of an example of a via-first dual damascene process. Via-first refers to the order in which the trench and via features are etched. For via-first, the via feature is etched through the entire thickness of the ILD before the trench feature is etched through a portion of the ILD thickness. Conversely, for trench-first, the trench feature is etched partially through the thickness of the ILD before the via feature is etched through the remaining ILD thickness at the base of the trench feature. While a via-first process will be illustrated, the present invention is also applicable to trench-first and other dual damascene processes as well as single damascene processes.

As discussed in more detail below, in one embodiment of the invention, a porous low k material is employed as an inter-level dielectric layer, but protects the porous low k material during the CMP process by forming a more resilient nonporous (or less porous) low k material over the porous low k material. To prevent the formation of the previously discussed recess, the nonporous low k material is only formed after the trench or via has been etched and filled with a conductive material that has undergone a CMP process. However, since the CMP process is performed prior to deposition of the nonporous low k material, a damaged layer is generally formed in the porous low k material. In the present invention, this damaged layer is removed prior to deposition of the nonporous low k material. Using this technique porous low k materials, which generally do not withstand the CMP process, can be used for ILDs.

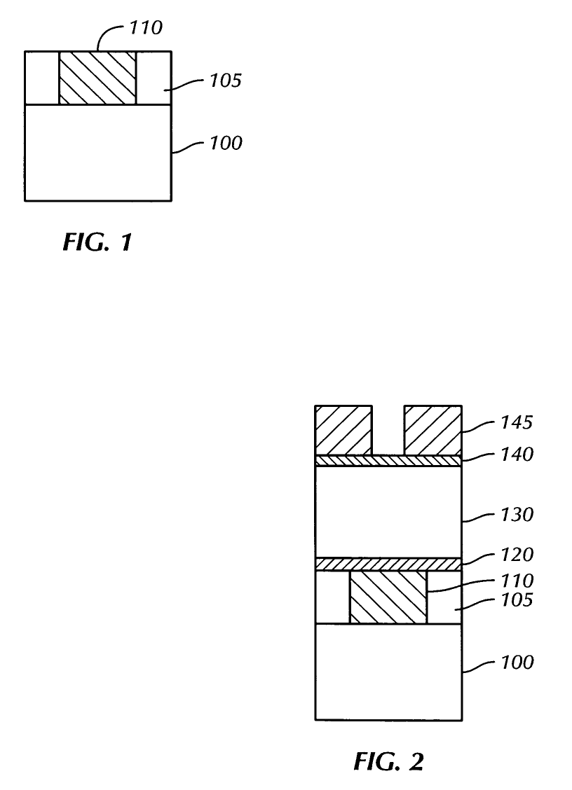

A method of fabricating dual damascene interconnections according to an embodiment of the present invention will now be described with reference to FIG. 1 through 13. Of course, the present invention is equally applicable to a single damascene interconnect structure.

As shown in FIG. 1, a substrate 100 is prepared. A lower ILD layer 105 including a lower interconnection 110 is formed on the substrate 100. The substrate 100 may be, for example, a silicon substrate, a silicon on insulator (SOI) substrate, a gallium arsenic substrate, a silicon germanium substrate, a ceramic substrate, a quartz substrate, or a glass substrate for display. Various active devices and passive devices may be formed on the substrate 100. The lower interconnection 110 may be formed of various interconnection materials, such as copper, copper alloy, aluminum, and aluminum alloy. The lower interconnection 110 is preferably formed of copper because of its low resistance. Also, the surface of the lower interconnection 110 is preferably planarized.

Referring to FIG. 2, a barrier or etch stop layer 120, a low-k ILD layer 130, and a capping layer 140 are sequentially stacked on the surface of the substrate 100 where the lower interconnection 110 is formed, and a photoresist pattern 145 is formed on the capping layer 140 to define a via. It should be noted that capping layer 140 is optional and need not be employed in all embodiments of the invention.

The barrier or etch stop layer 120 is formed to prevent electrical properties of the lower interconnection 110 from being damaged during a subsequent etch process for forming a via. Accordingly, the etch stop layer 120 is formed of a material having a high etch selectivity with respect to the ILD layer 130 formed thereon. In one embodiment, the etch stop layer 120 is formed of SiC, SiN, or SiCN, having a dielectric constant of 4 to 5. The etch stop layer 120 is as thin as possible in consideration of the dielectric constant of the entire ILD layer, but thick enough to properly function as an etch stop layer.

The ILD layer 130 is formed of a low k material such as a porous dielectric material. Typically, the porous dielectric material comprises a porous low-k material having a dielectric constant (k) value of 3.0 or lower. In some cases the porous dielectric material may have a dielectric constant of less than about 2.5. For example, the porous dielectric material may comprise a material having a k value of about 3.0 or less with a porogen introduced in order form pores, which lowers the dielectric constant to 2.7 or less, and more preferably about 2.5 or less, e.g. 1.8 or 1.9. Typically, the more pores formed in the material, the lower the dielectric constant k of the dielectric material will be. The ILD layer 130 may have a thickness of few thousand angstroms for example. Alternatively, the porous dielectric material may comprise other thicknesses. The porous dielectric material may be selected from a wide range of materials, including, without limitation, comprise porous methylsilsesquioxane (MSQ), porous inorganic materials, porous CVD materials, porous organic materials, or combinations thereof.

One widely used approach that can be employed to form porous low k materials relies on the incorporation of a thermally degradable material (porogen) within a host thermosetting matrix. Upon heating, the matrix material crosslinks, and the porogen undergoes phase separation from the matrix to form nanoscopic domains. Subsequent heating leads to porogen decomposition and diffusion of the volatile by-products out of the matrix. Under optimized processing conditions, a porous network results in which the pore size directly correlates with the original phase-separated morphology. Two commercially available materials of this type are Dow Chemical's porous SiLK and IBM's DendriGlass materials.

Dendriglass is a chemical composition containing MSQ and various amounts of a second phase polymeric material, i.e. a pore-forming agent. Dendriglass can be made into a porous film with a dielectric constant in a range between about 1.3 and about 2.6 depending on the amount of the second phase material added to the film. The second phase polymeric material, or the pore-forming agent, is a material that is usually a long chained polymer which can be decomposed and volatilized and driven from the matrix material, i.e. MSQ, after the film has been cured in a first curing process. Dendriglass can be spin-coated and then cured at a temperature of less than about 350° C. Finally, the structure is heated to a temperature higher than the first temperature, or preferably higher than about 400° C. to 450° C., for a time period long enough to drive out the second phase polymeric material from the Dendriglass resulting in a porous low-k dielectric film.

Referring again to FIG. 2, after formation of the porous ILD layer 130, capping layer 140 is formed thereabove. The capping layer 140 prevents the porous ILD layer 130 from being damaged when damascene interconnections are planarized using chemical mechanical polishing (CMP). The capping layer 140 also serves as a hardmask during the subsequent etching steps used to form vias and trenches. The capping layer 140 may be formed of any appropriate material such as SiO₂, SiOF, SiON, SiCOH, SiC, SiN, or SiCN. For example, in conventional processes an organosilicon compound such as tetraethoxysilane (TEOS) is used to form an SiO₂ capping layer by PECVD. As previously mentioned, the capping layer 140 must generally be sufficient thick to prevent damage to the underlying ILD layer 130 during subsequent CMP processing.

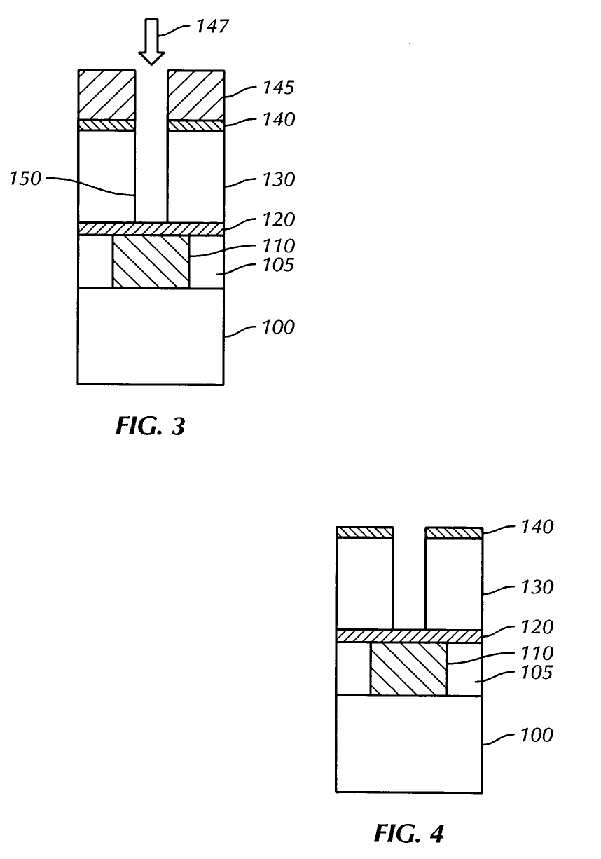

After formation of porous ILD layer 130 and capping layer 140, the process continues by forming the via photoresist pattern 145 by depositing a layer of a photoresist and then performing exposure and developing processes using a photo mask defining a via. Referring to FIG. 3, the ILD layer 130 is anisotropically etched (147) using the photoresist pattern 145 as an etch mask to form a via 150. The ILD layer 130 can be etched, for example, using a reactive ion beam etch (RIE) process, which uses a mixture of a main etch gas (e.g., CₓF_{y} and CₓH_{y}F_{z}), an inert gas (e.g. Ar gas), and possibly at least one of O₂, N₂, and COₓ. Here, the RIE conditions are adjusted such that only the porous ILD layer 130 is selectively etched and the etch stop layer 120 is not etched.

Referring to FIG. 4, the via photoresist pattern 145 is removed using a stripper. If the photoresist pattern 145 is removed using O₂-ashing, which is widely used for removing a photoresist pattern, the ILD layer 130, which often contains carbon, may be damaged by the O₂-based plasma. Thus, the photoresist pattern 145 alternatively may be removed using an H₂-based plasma. In some cases, the via 150 is filled with a back filling material (not shown) such as an organic polymer that is spin-coated and baked. The back-filling material, which serves to protect the shape of the via while the trench is etched, is subsequently removed, for example, by an oxygen plasma.

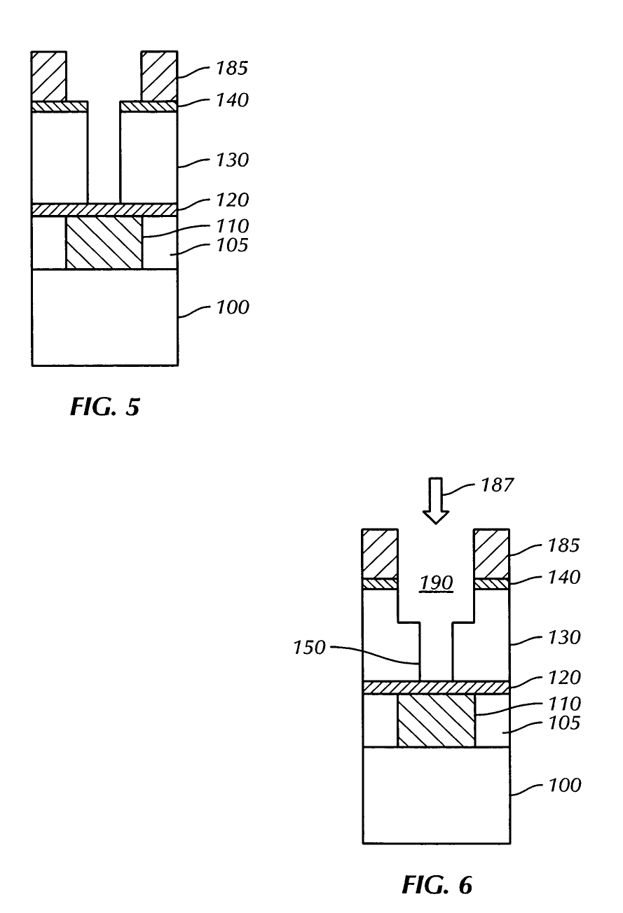

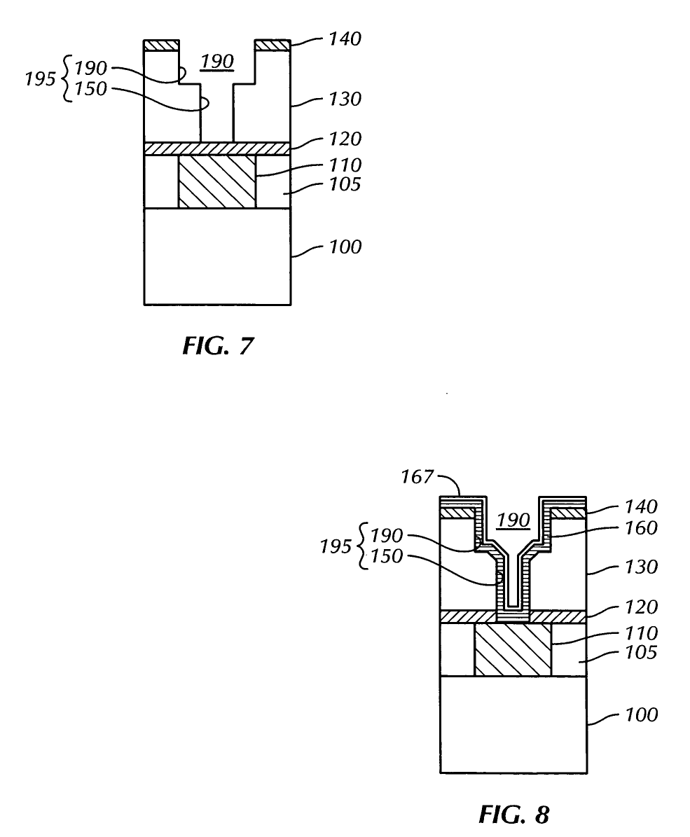

Referring to FIG. 5, a trench photoresist pattern 185 is formed, followed by formation of a trench 190 in FIG. 6. The capping layer 140 is etched using the photoresist pattern 185 as an etch mask, and then the ILD layer 130 is etched (187) to a predetermined depth to form the trench 190. The resulting structure, shown in FIG. 7, defines a dual damascene interconnection region 195, which includes the via 150 and the trench 190.

Referring to FIG. 8, the etch stop layer 120 exposed in the via 150 is etched until the lower interconnection 110 is exposed, thereby completing the dual damascene interconnection region 195. The etch stop layer 120 is etched so that the lower interconnection 110 is not affected and only the etch stop layer 120 is selectively removed.

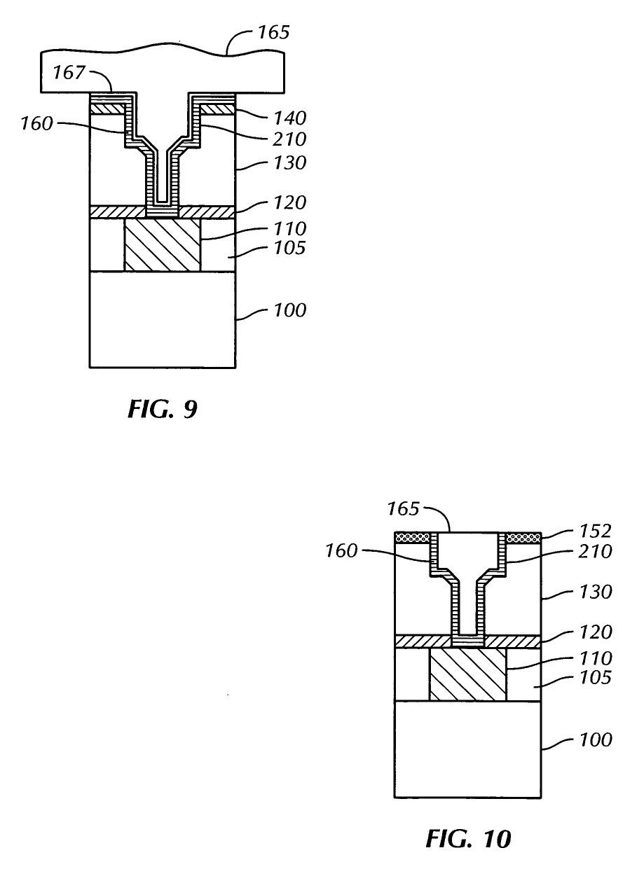

A barrier layer 160 is formed on the dual damascene interconnection region 195 (as well as capping layer 140) to prevent the subsequently formed conductive layer from diffusing into ILD layer 130. The barrier layer 160 is generally formed from a conventional material such as tantalum, tantalum nitride, titanium, titanium silicide, ruthenium or zircuonium. After formation of the barrier layer 160 a copper seed layer 167 is formed, which is required for the subsequent deposition of bulk copper. That is, copper electroplating occurs on top of the copper seed layer 167. Referring to FIG. 9, the bulk copper layer 165 is formed in the dual damascene interconnection region 195 by an electroplating process. The excess metal and barrier material above the interconnects is then removed by chemical mechanical polishing (CMP), thereby forming a dual damascene interconnection. The CMP process involves introducing a chemical slurry to the surface of the ILD while using a rotating polishing pad to remove excess metal and planarize the surface of the ILD.

More specifically, in a CMP process, the structure is positioned on a CMP pad located on a platen or web. A force is then applied to press the structure against the CMP pad. The CMP pad and the structure are moved against and relative to one another while applying the force to polish and planarize the surface. A polishing solution, often referred to as polishing slurry, is dispensed on the CMP pad to facilitate the polishing. The polishing slurry typically contains an abrasive and is chemically reactive to selectively remove the unwanted material, for example, the metal and barrier layers, more rapidly than other materials, for example, a dielectric material.

As previously noted, the capping layer 140 is provided to prevent damage to the ILD layer 130 during the CMP process. If the capping layer is too thin or not present, significant damage may occur to the underlying ILD layer during CMP processing. Such damage may cause, for example, fluorine addition and carbon depletion from the porous low-k material adjacent to the etched surface. In addition to a higher effective k, the resultant structures are susceptible to void formation, outgassing and blister formation. The voids in turn may cause an increase in leakage current at elevated voltages and a reduction in breakdown voltage.

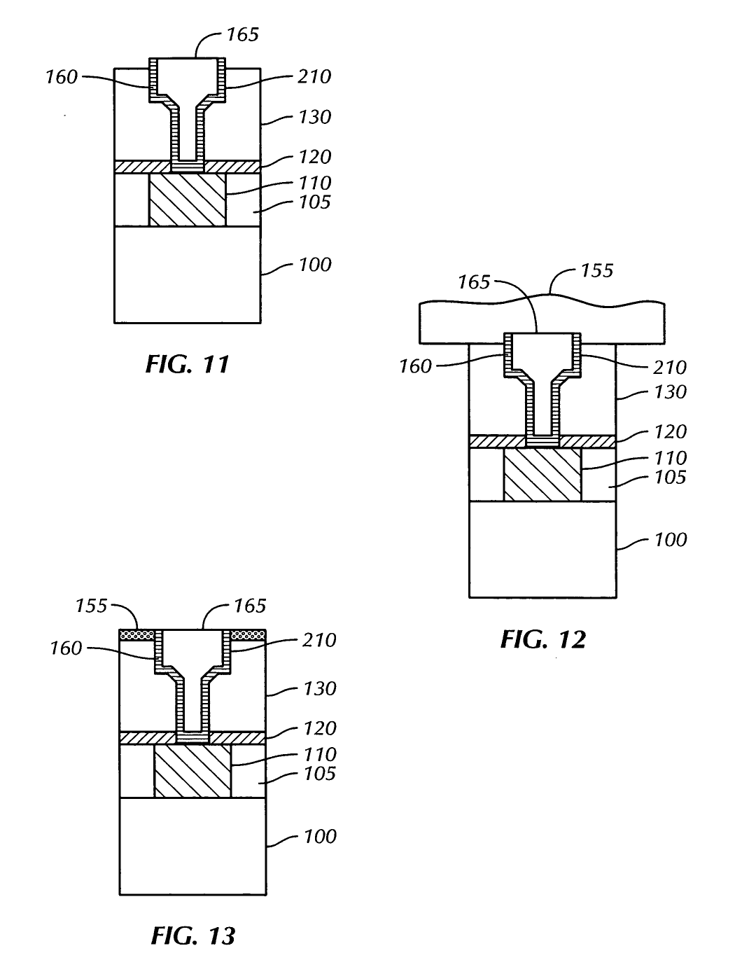

In accordance with the present invention, the damaged portion of the ILD layer is removed by an etching process. As shown in FIG. 10, the portion of ILD layer 130 that is damaged by the CMP process is represented by damaged layer 152. The etching may be performed by any appropriate technique that selectively etches the damaged ILD layer 152 but not the intact, undamaged ILD layer underlying the damaged portion of the ILD layer. The etching process that is employed, may be, for example, a wet etching process using, for instance, fluoride-based aqueous chemistries. Examples of fluoride-based aqueous chemistries include HF and buffered HF. The etching process selectively etches the damaged layer 152 but not the intact ILD layer 130 because the intact ILD layer 130 is hydrophobic and therefore the wet etchant does not diffuse into it. In contrast, the damaged layer 152 is relatively hydrophilic and is thus readily etched by the wet etchant. FIG. 11 shows the structure after the damaged ILD layer 152 has been removed.

After the damaged ILD layer 152 is etched a nonporous low k material (or a low k material that is less porous than ILD layer 130 and which is also sufficiently resilient to serve as a hardmask) is deposited to effectively replace the damaged ILD layer 152. The nonporous low k material, designated ILD layer 155 in FIG. 12, generally has a dielectric constant greater than the dielectric constant of the porous low k material. For instance, in some embodiments of the invention, the nonporous ILD layer 155 may have a dielectric constant between about 2.6 and 3.3, whereas the porous low k ILD 130 may have a dielectric constant of less than about 2.5. The nonporous ILD 155 is formed of a hybrid low-k dielectric material such as SiOCH, which has advantages of organic and inorganic materials. That is, the ILD 155 is formed of a hybrid low-k dielectric material having low-k characteristics, which can be formed using a conventional apparatus and process, and which is thermally stable. For example, in addition to SiOCH, the nonporous ILD 155 may be formed of low-k organosilicon material such as Black Diamond™, CORAL™, or a similar material. The ILD 155 can be formed using chemical vapor deposition (CVD), and more specifically, plasma-enhanced CVD (PECVD). The ILD 155 may be also formed from low k materials such as spin-on organics and organo silicates. The ILD 155 is formed to a thickness of about a few hundred angstroms or other appropriate thicknesses determined by those skilled in the art. Finally, nonporous ILD 155 is planarized using CMP, as shown in FIG. 13.

Although various embodiments are specifically illustrated and described herein, it will be appreciated that modifications and variations of the present invention are covered by the above teachings and are within the purview of the appended claims without departing from the spirit and intended scope of the invention. For example, those of ordinary skill in the art will recognize that the via-first dual damascene process described with reference to FIGS. 1 through 13 can be applied to a trench-first dual damascene process.

1. A method of fabricating a damascene interconnection, the method comprising:
(a) forming on a substrate a porous low k dielectric layer;
(b) forming a resist pattern over the low k dielectric layer to define a first interconnect opening;
(c) etching the porous low k dielectric layer through the resist pattern to form the first interconnect opening;
(d) removing the resist pattern;
(e) applying a barrier layer to line the first interconnect opening;
(f) forming an interconnection by filling the first interconnect opening with a conductive material;
(g) planarizing the interconnection to remove excess material;
(h) removing a portion of the porous low k dielectric layer damaged by the planarizing step (g);
(i) applying a nonporous low k dielectric layer after the damaged portion of the porous low k dielectric layer is removed; and
(j) planarizing the interconnection by removing an excess portion of the nonporous low k dielectric layer.

2. The method of claim 1 further comprising forming a capping layer on the porous dielectric layer and in step (c) etching the capping layer and the porous low k layer through the resist pattern.

3. The method of claim 1 wherein the step of removing the damaged portion of the dielectric layer is performed by a wet etching process.

4. The method of claim 3 wherein the wet etching process employs HF as an etchant.

5. The method of claim 1 wherein the porous low k dielectric has a dielectric constant less than about 2.5 and the nonporous low k dielectric has a dielectric constant of between about 2.6 and 3.3.

6. The method of claim 1 wherein the step of etching the porous low k dielectric layer is performed by Reactive Ion Etching (RIE).

7. The method of claim 1 wherein the porous low k layer includes SiLK™.

8. The method of claim 1 wherein the porous low k layer includes DendriGlass™.

9. The method of claim 1 wherein the nonporous low k layer includes SiOCH.

10. The method of claim 1 wherein the nonporous low k layer is selected from the group consisting of Black Diamond™ or Coral™.

11. The method of claim 1 wherein the first interconnect opening comprises a via.

12. The method of claim 1 wherein the first interconnect opening comprises a via and a trench connected thereto.

13. The method of claim 1 wherein the planarizing step (g) is performed by CMP.

14. The method of claim 1 wherein the damascene interconnection is a dual damascene interconnection and further comprising the steps of applying a second resist pattern over the capping layer and etching the porous dielectric layer to form a second interconnect opening that is connected to said first interconnect opening and wherein the step of forming the first and second interconnect openings includes filling the first and second interconnect openings with the conductive material.

15. The method of claim 1 wherein the conductive material is copper.

16. An integrated circuit having a damascene interconnection constructed in accordance with the method of claim 1.

17. A method of fabricating a damascene interconnection, the method comprising:
(a) forming on a substrate a first low k dielectric layer;
(b) forming a resist pattern over the first low k dielectric layer to define a first interconnect opening;
(c) etching the first low k dielectric layer through the resist pattern to form the first interconnect opening;
(d) removing the resist pattern;
(e) applying a barrier layer to line the first interconnect opening;
(f) forming an interconnection by filling the first interconnect opening with a conductive material;
(g) planarizing the interconnection to remove excess material;
(h) removing a portion of the first low k dielectric layer damaged by the planarizing step (g);
(i) applying a second low k dielectric layer after the damaged portion of the first low k dielectric layer is removed, wherein the second low k dielectric layer is more mechanically resilient than the first low k dielectric layer, thereby allowing it to serve as a hardmask; and
(j) planarizing the interconnection by removing an excess portion of the second low k dielectric layer.

18. The method of claim 17 wherein the first low k dielectric layer includes a porous material and the second low k dielectric layer includes a nonporous material.
